(19) United States
(12) Patent Application Publication
(10) Pub. No.: US 2022/0250285 A1
(43) Pub. Date: Aug. 11, 2022

(54) Cleaning sheet, manufacturing method of semiconductor device and manufacturing method of cleaning sheet

(71) Applicant: TOHOKU BUTSURYU Co., Ltd., Yamagata (JP)

(72) Inventors: Kenji MAEYAMA, Yamagata (JP); Kiyoshi TSUCHIDA, Yamagata (JP)

(21) Appl. No.: 17/629,807

(22) PCT Filed: Nov. 12, 2020
(86) PCT No.: PCT/JP2020/042341

§ 371 Date: Jan. 25, 2022

(30) Foreign Application Priority Data
Nov. 15, 2019 (JP) 2019-207284

(51) Int. Cl. B29C 33/72; H01L 21/02; H01L 21/56; D21H 17/48

(52) U.S. Cl. CPC B29C 33/722; H01L 21/02082; B29L 2031/34; D21H 17/48; H01L 21/566

(57) ABSTRACT

A cleaning sheet is interposed between resin molding mold surfaces and cleans the resin molding mold surfaces with a cleaning resin. The cleaning sheet is composed of a paper material, and is impregnated with a thermosetting resin and cured from the front surface layer to the back surface layer of the paper material.

### TECHNICAL FIELD

The present invention relates to a cleaning sheet, manufacturing method of semiconductor device and manufacturing method of cleaning sheet.

### BACKGROUND ART

Since molding is repeated many times in the resin molding process of a semiconductor device for resin molds, dirt such as resin burrs, oxide film, oil or dust accumulates inside the mold filled with the molding resin, that is, inside the cavities, runners, air vents, and cull blocks of the upper and lower molds that form a pair of molds.

It is necessary to clean the mold every fixed number of shots since such dirt adversely affect mold quality, and in particular, when the mold becomes dirty and the mold release decreases, stress is applied to the semiconductor chip inside the molded product when the product is released from the pair of first mold and second mold, causing cracks in the chip, and staining due to surface stains on the molded product and deterioration of mark strength may occur.

To meet such demands, as described in Patent Document 1, a method has been proposed in which a lead frame (hereinafter referred to as a dummy lead frame) on which a semiconductor chip is not mounted is clamped between the main surfaces (mating surfaces) of the molding die, and a cleaning resin formed of a melamine resin or the like is injected into a molding die and cured to attach stains to the surface of the cleaning resin, and the stains are removed together with the cleaning resin for cleaning.

Further, in Patent Document 2, a method for cleaning a mold, which comprises a process of clamping a sheet-like member made of cotton cloth (nonwoven fabric) impregnated with cleaning resin and permeable between opened molds, and filling the cavity of the closed mold with the cleaning resin in a molten state, has been proposed.

Further, in Patent Document 3, a method for cleaning a mold, which comprises a process of installing a mold cleaning sheet, which is made of paper and does not allow resin and cleaning resin to infiltrate and penetrate from the front side to the back side of the paper, in the mold and clamping by the first mold and the second mold, supplying the cleaning resin from the pot, and filling the cavity block with the cleaning resin through the opening of the mold cleaning sheet, has been proposed.

### CITATION LIST

### Patent Document

[Patent Document 1]

Japanese Unexamined Patent Publication No. 1989-95010.
[Patent Document 2]

Japanese Unexamined Patent Publication No. 1994-254866.
[Patent Document 3]

Japanese Unexamined Patent Publication No. 2007-208158.

### SUMMARY OF INVENTION

### Technical Problem

However, the technique described in Patent Document has a problem that the cost is high because an expensive dummy frame is used as a cleaning sheet.

Further, the technique described in Patent Documents 2 and 3 discloses a cleaning sheet using paper or a non-woven fabric, but a mere paper or non-woven fabric has problems in dust generation and abrasion resistance.

Therefore, in view of the above problems, the present invention provides a cleaning sheet having excellent rigidity, dust generation, water repellency, etc., a method for manufacturing a semiconductor device, and a method for manufacturing a cleaning sheet at low cost while the cleaning sheet is made of a paper material.

### Solution of Problem

Embodiment 1: At least one embodiment of the present invention propose a cleaning sheet that is interposed between the resin molding mold surfaces and cleans the resin molding mold surface with a cleaning resin, characterized in that: it is made of a paper material, which is impregnated with a thermosetting resin and cured from the front surface layer to the back surface layer of the paper material.

Embodiment 2: At least one embodiment of the present invention propose a cleaning sheet characterized in that the thermosetting resin is cured by heating it at 200° C. to 300° C. for a predetermined time.

Embodiment 3: At least one embodiment of the present invention propose a cleaning sheet characterized in that the paper material contains cellulose as a main component.

Embodiment 4: At least one embodiment of the present invention propose a cleaning sheet characterized in that the thermosetting resin is a phenol resin.

Embodiment 5: At least one embodiment of the present invention propose a cleaning sheet wherein, the cleaning sheet is placed between the first mold and the second mold of a mold consisting of a pair of first molds and a second mold having a cavity block which is a mounting area of a lead frame and a pot holder consisting of a plurality of pots for adding cleaning resin, characterized in that, the cleaning sheet has an opening corresponding to at least the cavity block when it is arranged between the first mold and the second mold.

Embodiment 6: At least one embodiment of the present invention propose method for manufacturing a semiconductor device, which comprises a step of cleaning the mating surfaces of a mold consisting of a pair of first mold and second mold having a cavity block which is a mounting area of a lead frame and a pot holder consisting of a plurality of pots into which resin is added, using the cleaning sheet, characterized in that it has the steps of; preparing the cleaning sheet having an opening corresponding to at least the cavity block when placed between the first mold and the second mold; installing the cleaning sheet in the mold and clamping the cleaning sheet with the first mold and the second mold; supplying the cleaning resin from the pot and filling the cavity block with the cleaning resin through the opening of the cleaning sheet; releasing the cleaning resin and the cleaning sheet from the mold after curing the cleaning resin.

Embodiment 7: At least one embodiment of the present invention propose a method for manufacturing a semiconductor device, characterized in that the semiconductor device includes at least a DIL-P, a QFP, a MAP, a CSP, a BGA, a diode, and a transistor.

Embodiment 8: At least one embodiment of the present invention propose a method for manufacturing a cleaning sheet, characterized in that it has the steps of: impregnating paper material containing cellulose as the main component with phenol resin; curing the phenol resin by performing a heat treatment including a treatment of heating the paper material impregnated with the phenol resin at at least 200° C. to 300° C. for a predetermined time.

According to one or more embodiments of the present invention, there is an effect that it can provide a cleaning sheet that is made of paper and has excellent rigidity, dust generation, water repellency, etc. at low cost, a manufacturing method of semiconductor device and manufacturing method of cleaning sheet.

### BRIEF DESCRIPTION OF DRAWINGS

FIG. 1 is a perspective view of the cleaning sheet according to the embodiment of this invention.

FIG. 2 is a figure which illustrates the impregnation process of the cleaning sheet according to the embodiment of this invention.

FIG. 3 is a figure which illustrates the experimental result in the impregnation process of the cleaning sheet according to the embodiment of this invention.

FIG. 4 is a figure which illustrates the thermosetting process of the cleaning sheet according to the embodiment of this invention.

FIG. 5 is a figure which illustrates the die-cutting process of the cleaning sheet according to the embodiment of this invention.

FIG. 6(A) is a figure which shows the cross-sectional observation image A of the conventional product, and FIG. 6(B) is a figure which shows the cross-sectional observation image B of an invention product with respect to the cleaning sheet according to the embodiment of this invention.

FIG. 7 is a figure which shows the hardness of the conventional product and the invention product with respect to the cleaning sheet according to the embodiment of this invention.

FIG. 8 is a figure which shows the temperature and weight phenomenon of the conventional product and the invention product with respect to the cleaning sheet according to the embodiment of this invention.

FIG. 9 is a figure which shows the tear strength and the tensile strength of the conventional product and the invention product with respect to the cleaning sheet according to the embodiment of this invention.

FIG. 10 is a figure which shows the result of the dust generation property test of the conventional product, the invention product, and the non-woven fabric regarding the cleaning sheet according to the embodiment of this invention.

FIG. 11 is a figure which shows the result of the sheet immersion test of the conventional product and the invention product with respect to the cleaning sheet according to the embodiment of this invention.

FIG. 12 is a perspective view which shows an example of the structure of the transfer molding apparatus used in this invention.

FIG. 13 is a partial cross-sectional view for explaining the structure of the mold in the transfer molding apparatus of FIG. 12.

FIG. 14 is a plan view showing a lead frame on which a semiconductor chip is mounted.

FIG. 15 is a perspective view showing an example of the structure of a semiconductor device with a partial cross-section.

FIG. 16 is a cross-sectional view showing an example of the structure of a semiconductor device.

FIG. 17 is a cross-sectional process flow diagram showing an example of a manufacturing process of a semiconductor device.

FIG. 18 is a partial cross-sectional view of a mold showing a state in which a lead frame to which a semiconductor chip is bonded is placed in a mold.

FIG. 19 is a partial cross-sectional view of a mold showing a state in which a lead frame to which a semiconductor chip is bonded is placed in a mold, the mold is closed, and a mold resin is filled between the molds.

FIG. 20 is a partial cross-sectional view of a mold showing a state in which the mold is opened after filling the mold resin.

FIG. 21 is a partial cross-sectional view of a mold showing a state in which a mold cleaning sheet is placed in the mold.

FIG. 22 is a partial cross-sectional view of a mold showing a state in which a mold cleaning sheet is placed in a mold, the mold is closed, and a cleaning resin is filled between the molds.

### DESCRIPTION OF EMBODIMENTS

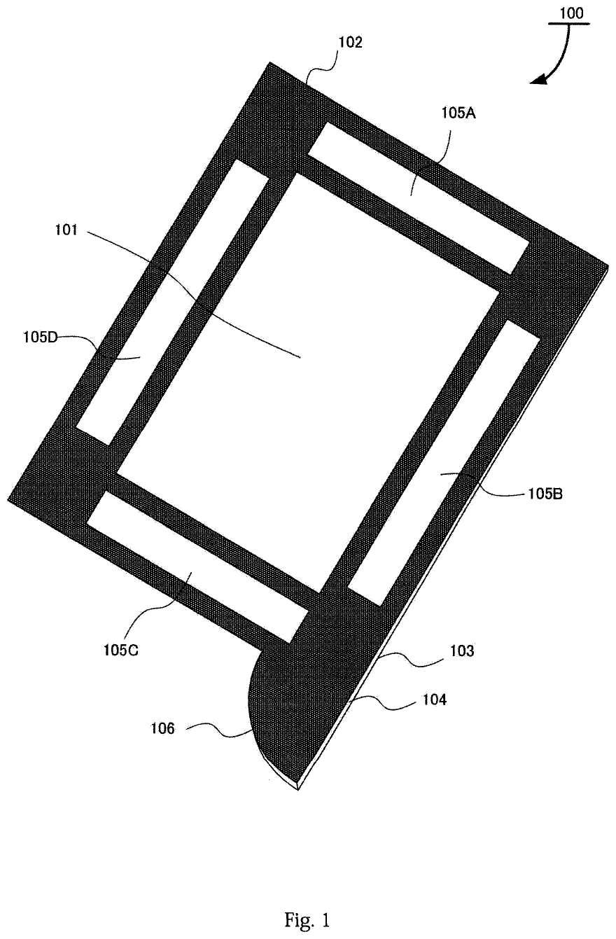

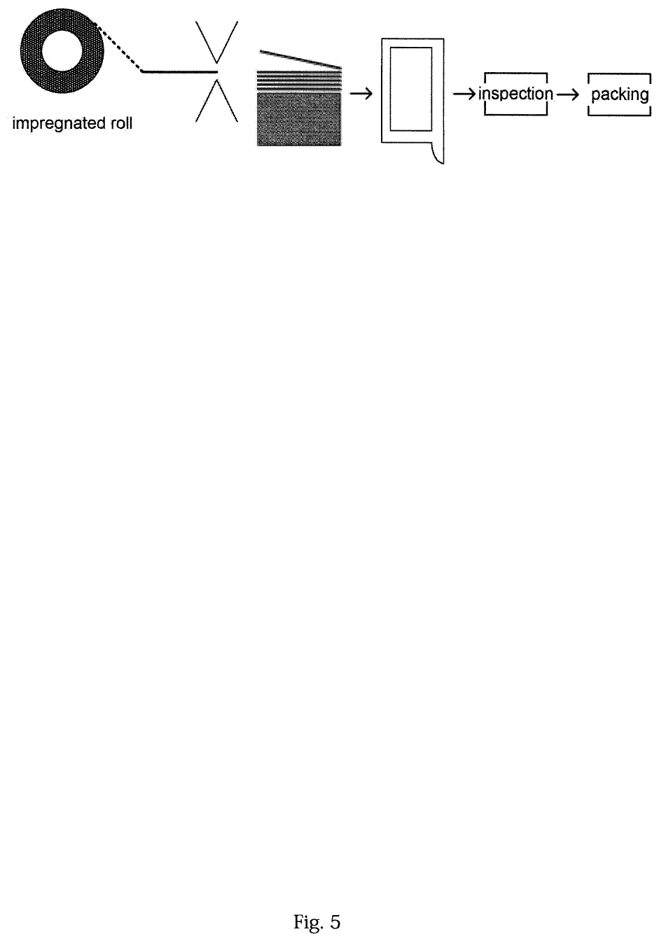

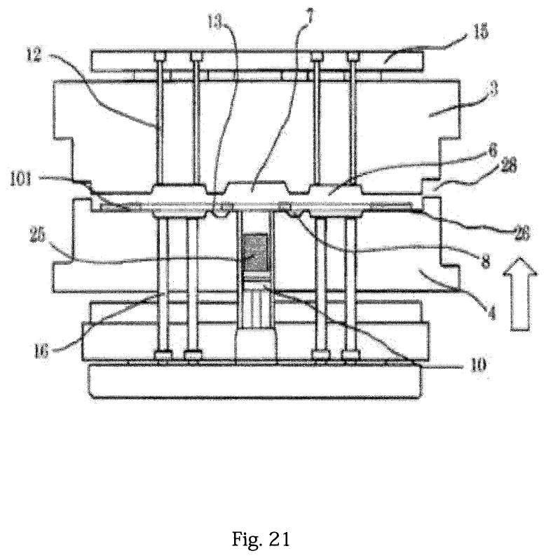

Hereinafter, embodiments of the present invention will be described with reference to FIGS. 1 to 22.

### <Configuration of a Cleaning Sheet>

The cleaning sheet 100 is obtained by impregnating a paper material containing cellulose as the main component with a thickness of about 0.40 mm, which does not cause resin leakage during molding, with a phenol resin, and thermosetting the phenol resin by a heat treatment including a treatment of heating the paper material impregnated with the phenol resin at at least 200° C. to 300° C. for a predetermined time, and unlike non-woven fabrics, the cleaning resin does not penetrate or pass through.

Specifically, the cleaning sheet 100 is made of a paper material, and is impregnated with a thermosetting resin from the front surface layer 102 to the back surface layer 103 of the paper material, and heat-cured.

As shown in FIG. 1, the cleaning sheet 100 is provided with an opening 101 in the center. Using this opening 101, cleaning resin is poured over the entire surface of the cavity block and the pot holder for cleaning.

The punching cross section 104 of the cleaning sheet 100 is impregnated and cured with a phenol resin, and the thickness thereof is, for example, about 0.50 mm.

In the cleaning sheet 100, openings 105A, 105B, 105C, and 105D for suppressing warpage of the entire sheet due to an external factor such as heat is provided parallel to the central portion in the length direction of each side of the opening 101 so as to surround the opening 101 of the central portion.

However, when the warp of the cleaning sheet 100 body is minute, it is not necessary to provide the openings 105A, 105B, 105C, and 105D.

The cleaning sheet 100 is provided with an arc-shaped handle portion 106 that can easily grip the cleaning sheet 100 when the cleaning sheet 100 is conveyed in the line, attached to the mold, or detached from the mold.

### <Manufacturing Method of Cleaning Sheet>

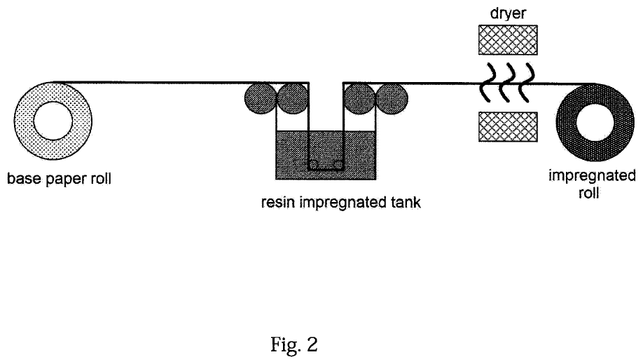

A method of manufacturing a cleaning sheet according to the present embodiment will be described with reference to FIGS. 2 to 5.

Firstly, a roll-shaped paper material containing cellulose with a basis weight of 377 g/m² and a thickness of about 0.50 mm as a main component is unwound and put into a resin impregnated tank filled with a phenol resin having a prepreg ratio of 10% diluted with methanol at a predetermined speed (time), and dry the front and back surface layers with a dryer while winding with a winder (impregnation step).

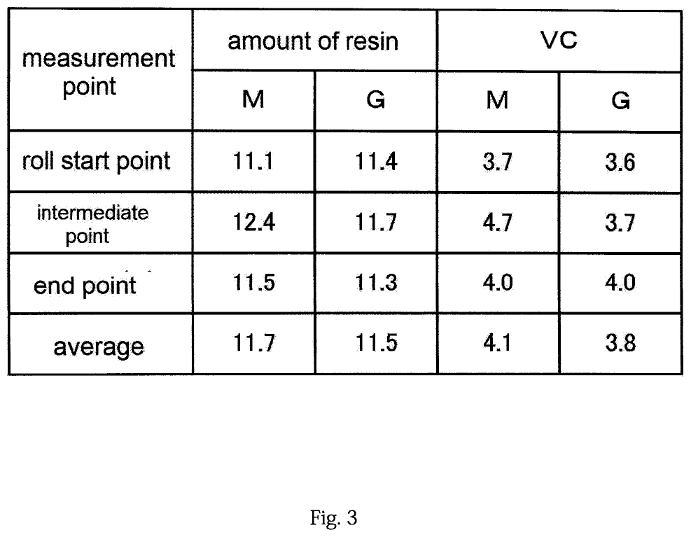

The result at this time is shown in FIG. 3.

In FIG. 3, “M” indicates the right end portion in the width direction of the paper material orthogonal to the transport direction of the roll-shaped paper material, and indicates the left end portion in the paper material width direction orthogonal to the transport direction of the roll-shaped paper material.

Further, “VC” is an abbreviation for Volatile Content, which indicates the amount of residual volatile matter, and in this experiment, indicates the residual amount of methanol used as a diluent.

As a result of the experiment, as shown in FIG. 3, there was no large variation in the amount of resin at the right end portion and the left end portion in the paper material width direction orthogonal to the transport direction of the roll-shaped paper material at the roll start point, the intermediate point, and the end point, and the amount of residual volatile matter was also at a level that was not a problem.

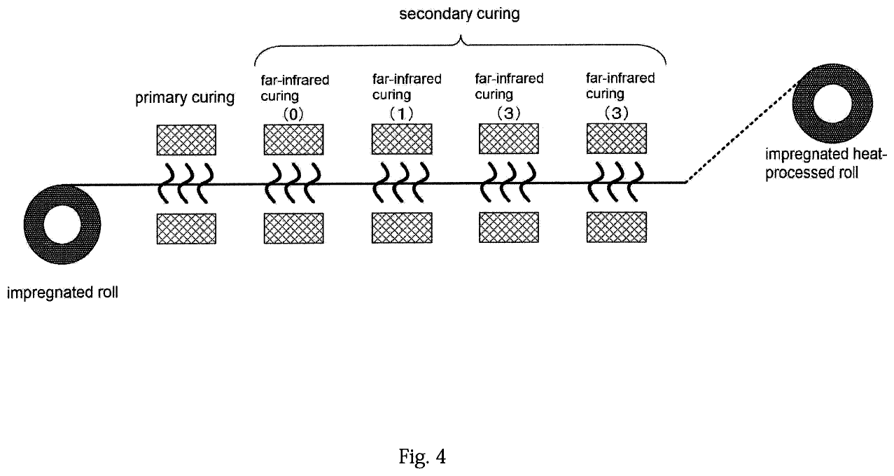

Next, in the impregnation step, a roll-shaped paper material containing cellulose as a main component impregnated with a phenol resin is unwound and thermosetting is performed (thermosetting step). As shown in FIG. 4, this thermosetting treatment is roughly divided into primary curing and secondary curing.

In the primary curing, the roll-shaped paper material that has undergone the impregnation step is thermally cured by the upper heater and the lower heater provided in the direction orthogonal to the transport direction of the roll-shaped paper material. At this time, the heating temperatures of the upper heater and the lower heater are both 200° C.

In the secondary curing, heat curing treatment is performed by far-infrared rays, and similar to the primary curing, the upper far-infrared heater and the lower far-infrared heater provided in the direction orthogonal to the transport direction of the roll-shaped paper material are used. In the secondary curing, four sets of the above-mentioned upper far-infrared heater and lower far-infrared heater are arranged at predetermined intervals, and the far-infrared output of each upper far-infrared heater and lower far-infrared heater is the same for each set ((0), (1), (2), (3)) of upper far-infrared heater and lower far-infrared heater, and the outputs of each set ((0), (1), (2), (3)) are 150 (V), 170 (V), 170 (V), and 210 (V) in order from the transport direction. Then, the thermoset roll-shaped paper material is wound by a winder.

The roll-shaped paper material that has been thermosetting in the thermosetting step is cut into rectangular paper materials of a predetermined size. A rectangular paper material of a predetermined size that has been cut is mounted on a press mold and punched (pressed) to form a cleaning sheet 100 having the shape shown in FIG. 1, and is packed through an inspection process.

### <Physical Properties Evaluation of the Cleaning Sheet>

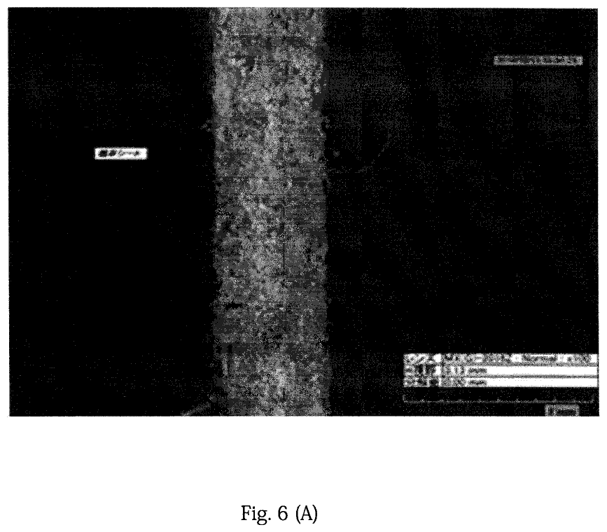

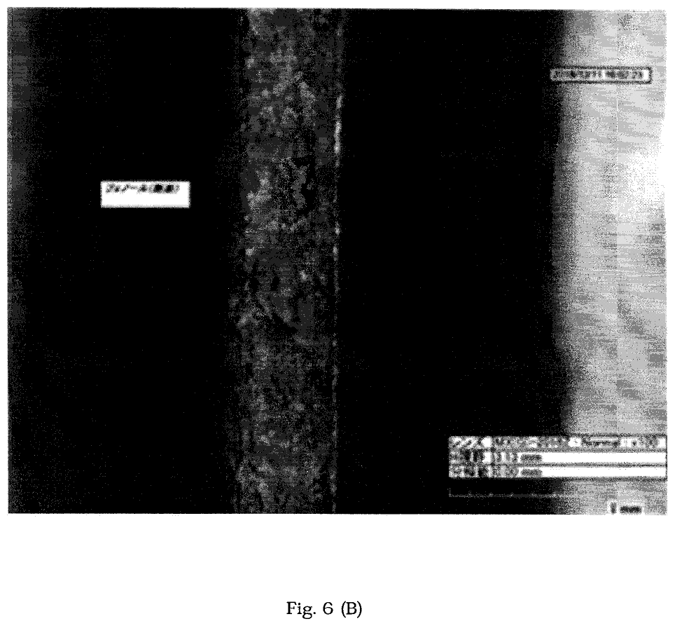

Hereinafter, the evaluation results of the physical property evaluation of the cleaning sheet 100 will be described with reference to FIGS. 6 to 11.

### [Paper Frame Sheet Evaluation Test]

Evaluation was performed using A) a conventional product and B) an invention product as test samples.

Here, the conventional product is the base paper name “NSA380 (manufactured by Oji Materia Co., Ltd.)”, and the invention product is the base paper name “NSA380” processed by the above-mentioned processing step. Hereinafter, similarly, they are described as “conventional product” and “invention product”.

The evaluation device used was KH-770 (manufactured by Hirox), and the image element used was a 1/1.8-inch CCD with 2.11 million pixels. Moreover, the magnification at the time of cross-section and surface observation was set to 100 times.

The evaluation image of the cross section is as shown in FIG. 6.

In FIG. 6, A is a cross-sectional image of a conventional product, and B is a cross-sectional image of an invention product.

According to the evaluation image of FIG. 6, the cross-sectional image A of the conventional product has some fluffing, but the cross-sectional image B of the invention product does not have the fluffing as seen in the cross-sectional image (A) of the conventional product.

Therefore, it can be said that the invention product has better characteristics.

### [Rockwell Hardness Test]

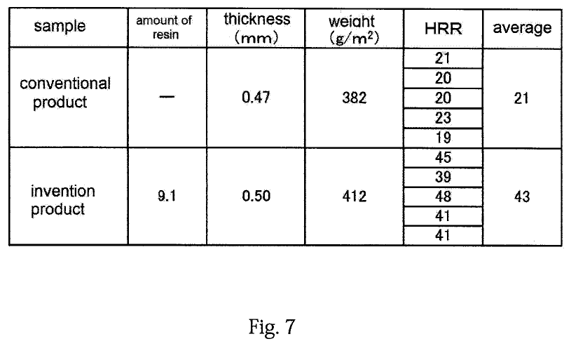

As shown in FIG. 7, evaluation was performed using a conventional product and an invention product as test samples.

The post-processed thickness of the invention product at this time was 0.50 mm, and the post-processed weight was 412 g/m².

The evaluation device was performed using a Rockwell hardness tester. The measurement was performed 5 times in total for the same conventional product and the invention product, and the relative evaluation was performed using the average value.

### <Conventional Product>

The Rockwell hardness of the conventional product was (HRR), 20 (HRR), 20 (HRR), 23 (HRR), 19 (HRR) on the R scale as a result of 5 measurements, and the average value was 21 (HRR).

### <Invention Product>

The Rockwell hardness of the invention product was 45 (HRR), 39 (HRR), 48 (HRR), 41 (HRR), 41 (HRR) on the R scale as a result of 5 measurements, and the average value was 43 (HRR).

From the test results of the Rockwell hardness test, the invention product showed a higher hardness value than the conventional product.

### [TG-DTA Test]

The TG test is a method of measuring the mass of a sample as a function of temperature while changing the temperature of the sample according to a certain program, and is a method of continuously measuring a change in mass of a sample when the sample is heated or cooled.

The quantitative measurement is possible according to this method, by detecting chemical changes such as dehydration/decomposition/oxidation/reduction and physical changes accompanied by mass changes such as sublimation/evaporation/desorption, and obtaining the weight difference (weight loss rate) before and after the change.

On the other hand, the DTA test is a method for detecting a thermal change generated in a sample due to a physical change or a chemical change that occurs when the sample is heated or cooled as a temperature difference from a reference substance.

The temperature difference from the reference substance is detected by the thermocouple welded to the sample holder heat-sensitive plate, and the behaviors such as decomposition, oxidation, reduction, dehydration, sublimation, evaporation, adsorption, desorption, transition, melting, solidification, crystallization hardening, and glass transition can be detected.

In this test, evaluation was performed using conventional products and invention products as test samples.

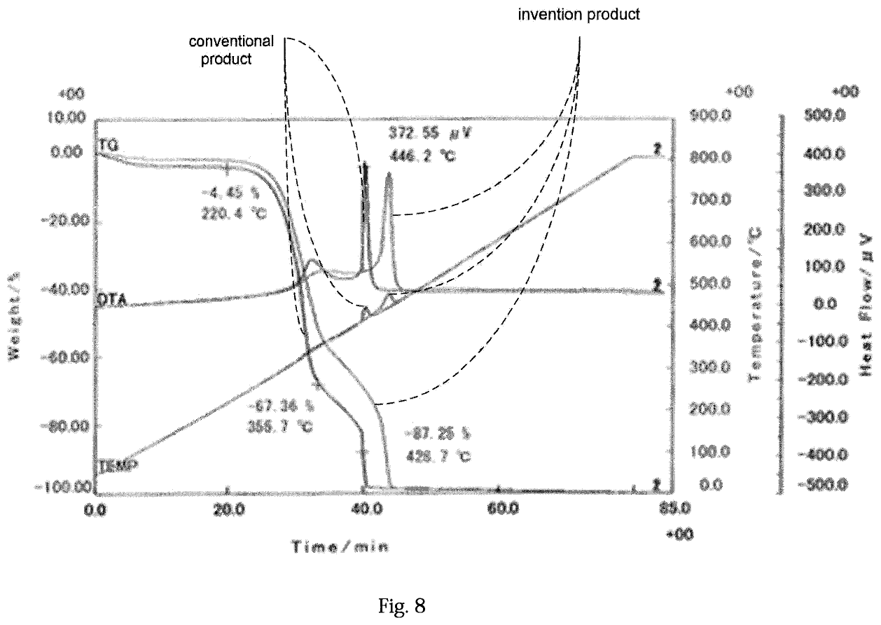

FIG. 8 is a graph in which the characteristics of the conventional product and the invention product in this test are overwritten. Further, in FIG. 8, the upward peak indicates the peak of heat generation.

According to FIG. 8, the peak of heat generation appears remarkably in both the conventional product and the invention product.

Further, the peak of the heat generation is shifted to the high temperature region in the invention product due to the influence of the impregnated and heat-cured phenol resin.

Furthermore, due to the influence of the impregnated and heat-cured phenol resin, the damping curve of the weight of the invention product is also steep because the damping point of the conventional product is earlier than the damping point of the invention product and is in the low temperature range.

### [Tear/Tensile Strength Evaluation Test]

Evaluation was performed using a conventional product and an invention product as test samples.

The evaluation device was an Elmendorf type textile tear strength tester (manufactured by Shimadzu Corporation).

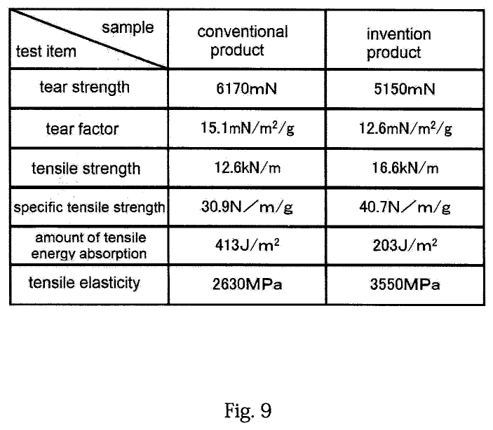

The evaluation results are as shown in FIG. 9, and the tear strength was 6170 mN for the conventional product and 5150 mN for the invention product, the tear factor was 15.1 mN/m²/g for the conventional product and 12.6 mN/m²/g for the invention product, the tensile strength was 12.6 kN/m for the conventional product and 16.6 kN/m for invention product, the specific tensile strength was 30.9 N/m/g for the conventional product and 40.7 N/m/g for the invention product, the amount of tensile energy absorption was 413 J/m² for the conventional product and 203 J/m² for the invention product, and the tensile elasticity was 2630 MPa for the conventional product and 3550 MPa for the invention product.

From the above results, it was evaluated that the invention product has higher rigidity and specific strength, lower flexibility, and less deformation than the conventional product.

### [Dust Generation Evaluation Test]

Evaluation was performed using a conventional product and an invention product as test samples.

The evaluation method was a tumbling method based on JIS B9923. The evaluation was carried out using one sheet each having a size of 15 cm×15 cm and not being washed.

The evaluation test used a tumbling type dust generation tester CW-HDT-102 (manufactured by Akado Seisakusho) as a testing machine, and the drum rotation speed was 30 rpm, the flow rate was 0.0102 m³/sec, the particle counter was Met One A2400B (manufactured by Hach Ultra Analytics), and the suction volume was 1 cubic foot/minute.

The evaluation test was conducted in the steps of:
1) A process of running a tumbling type dust generation tester installed in a clean room (cleanliness; ISO class 5 (class 100)) idle and confirming that the inside of the tester is dust-free.
2) A process of putting a sample into the drum of the testing machine and starting the operation of the testing machine.
3) A process of continuously measuring 5 times for 1 minute at a speed of 1 cubic foot/minute from 30 seconds after the start of operation of the testing machine, and using the average value of the remaining measured values excluding the maximum value and the minimum value as the dust generation number.

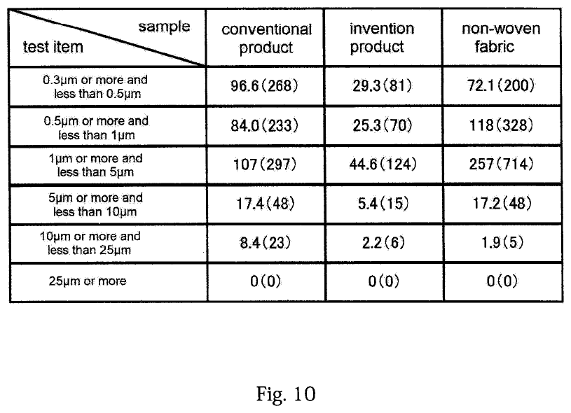

The evaluation results are as shown in FIG. 10, and the number of particles with a particle size of 0.3 μm or more and less than 0.5 μm was 96.6 particles/sec (268 particles/ft³) for the conventional product, 29.3 particles/sec (81 particles/ft³) for the invention product, 72.1 particles/sec (200 particles/ft³) for the non-woven fabric.

The number of particles with a particle size of 0.5 μm or more and less than fpm was 84.0 particles/sec (233 particles/ft³) for the conventional product, 25.3 particles/sec (70 particles/ft³) for the invention product, 118 particles/sec (328 particles/ft³) for the non-woven fabric.

The number of particles with a particle size of fpm or more and less than 5 μm was 107 particles/sec (297 particles/ft³) for the conventional product, 44.6 particles/sec (124 particles/ft³) for the invention product, 257 particles/sec (714 particles/ft³) for the non-woven fabric.

The number of particles with a particle size of 5 μmor more and less than 10 μm was 17.4 particles/sec (48 particles/ft³) for the conventional product, 5.4 particles/sec (15 particles/ft³) for the invention product, 17.2 particles/sec (48 particles/ft³) for the non-woven fabric.

The number of particles with a particle size of 10 μmor more and less than 25 μm was 8.4 particles/sec (23 particles/ft³) for the conventional product, 2.2 particles/sec (6 particles/ft³) for the invention product, 1.9 particles/sec (5 particles/ft³) for the non-woven fabric.

The number of particles with a particle size of 25 μm or more was 0 particles/sec (0 particles/ft³) for the conventional product, 0 particles/sec (0 particles/ft³) for the invention product, 0 particles/sec (0 particles/ft³) for the non-woven fabric.

From the above evaluation, for particles with a particle size of 10 μmor more, there is no significant difference between the conventional product, the invention product, and the non-woven fabric, but it is shown that the smaller the particle size, the more significantly superior the dust generation property of the invention product is to the conventional product and the non-woven fabric.

### [Water Penetration Evaluation Test]

Evaluation was performed using a conventional product and an invention product as test samples.

The evaluation test was carried out in the process of putting 360 ml of lukewarm water at 30° C. to 40° C. in a vat and immersing the conventional product and the invention in it for 5 minutes, a process in which the conventional product and the invention product soaked for 5 minutes are left to stand for 30 minutes, and a process of comparing the weight of the conventional product and the invention product before and after permeation. The weight was measured in units of 0.5 g.

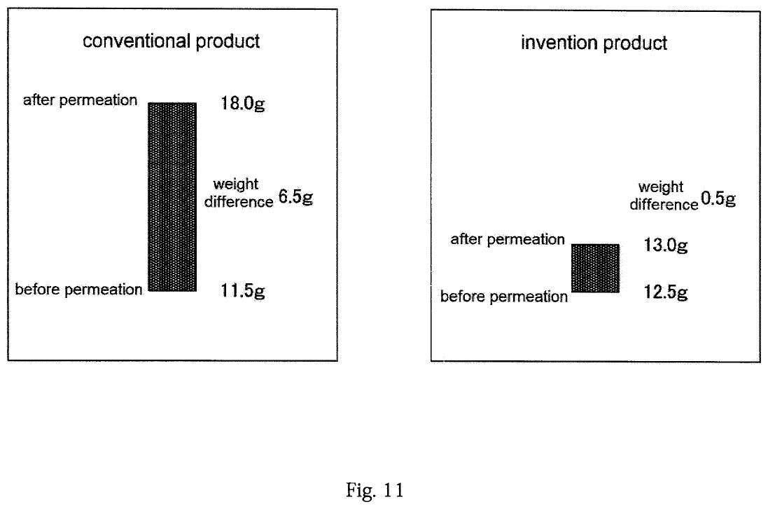

As shown in FIG. 11, the weight of the conventional product before the test was 11.5 g, the weight after the test was 18.0 g, and the weight difference before and after the test was 6.5 g.

On the other hand, the weight of the invention product before the test was 12.5 g, the weight after the test was 13.0 g, and the weight difference before and after the test was 0.5 g.

From this, it was evaluated that the conventional product has higher water absorption than the invention product, and conversely, the invention product has higher water repellency than the conventional product.

### <Manufacturing Method of Semiconductor Device>

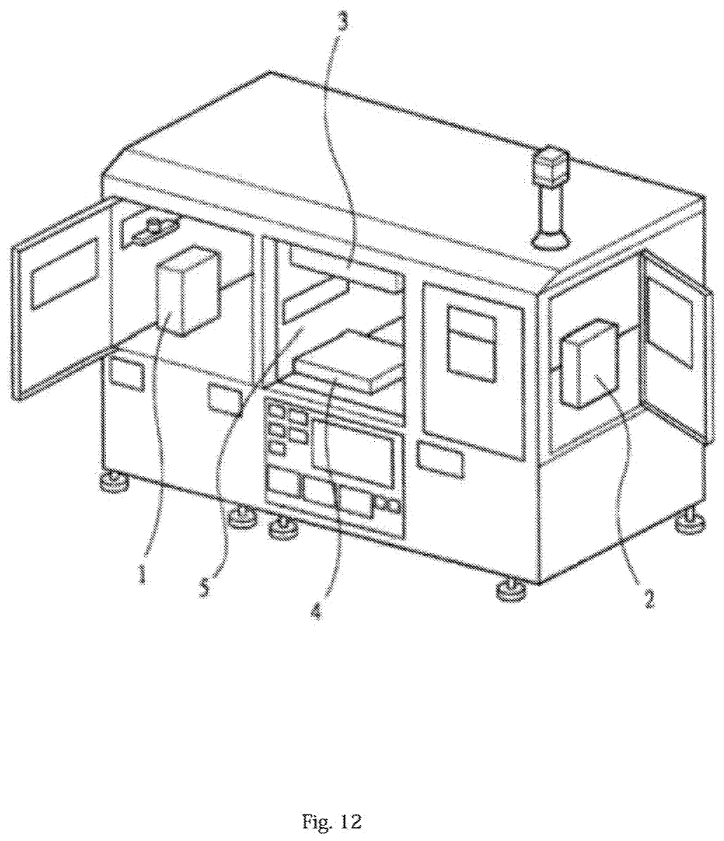

Hereinafter, a method for manufacturing a semiconductor device will be described with reference to FIGS. 12 to 22.

In the following, a transfer molding device will be described as an example as a device for performing molding.

The transfer molding device shown in FIG. 12 has a first mold 3 which is an upper mold, a second mold 4 which is a pair of lower molds thereof, and a mold 5 with a first mold 3 and a second mold 4, a loader 1 for carrying a work (here, for example, a lead frame having completed die bonding and wire bonding) into the mold 5, and an unloader 2 for taking out the work from the mold 5.

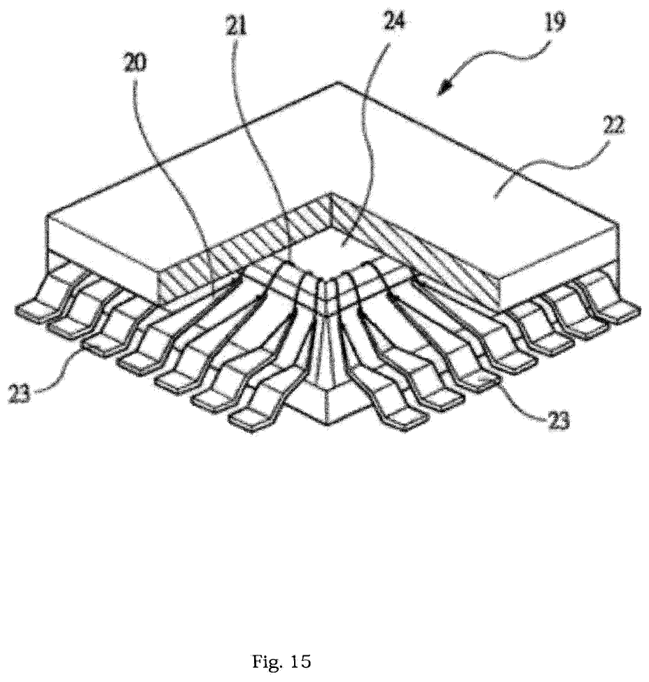

In the transfer mold apparatus, the lead frame 201 to which the semiconductor chip 24 (cf. FIG. 15) is bonded is carried into the mold 5 from the loader 1 shown in FIG. 12, and the semiconductor chip 24 and the like are resin-molded in the mold 5.

The QFP (Quad Flat Package) 19, which is a semiconductor device that has completed the molding, is carried out to the unloader 2 and accommodated therein.

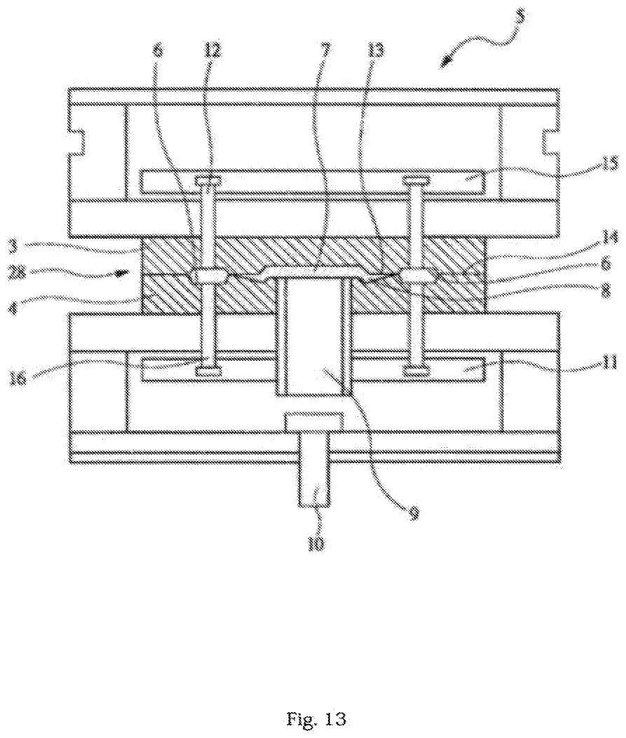

The mold 5 shown in FIG. 13 is provided with a cavity 6 having a shape corresponding to the mold portion 22 of the QFP 19 shown in FIG. 15, cull 7, runner 8, pot 9, plunger 10, ejector plates 11, 15, ejector pins 12, 16, gate 13, and air vent 14.

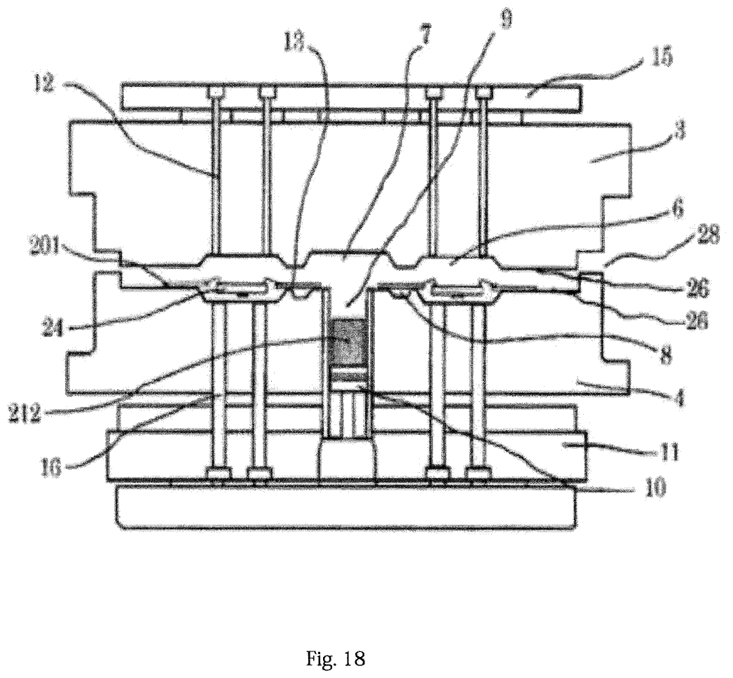

As shown in FIG. 18, on the mating surface 26 of the second mold 4 of the mold molding portion 28 (cf. FIG. 13), cavities 6 having a predetermined shape, which are first recessed portions in which the semiconductor chips 24 are arranged, are formed at a plurality of locations (the cavity 6 is also formed on the mating surface 26 of the first mold 3 in the same manner as the second mold 4). A molding resin such as a tablet 212 is set at a predetermined position of the second mold 4, and a plurality of cylinder-shaped pots 9 having a second recess are formed so as to penetrate through them, and as shown in FIG. 18, a cull 7 is provided in each portion of the first mold 3 corresponding to the pot 9.

From the cull 7, a plurality of runners 8 in which the plurality of cavities 6 are communicated are branched and formed, and in a state where the first mold 3 and the second mold 4 are in close contact with each other, the pot 9 is communicated with the plurality of cavities 6 via the cull 7 and the runner 8.

An air vent 14 is formed on the outside of the cavity 6 to allow the air in the cavity 6 to escape to the outside and complete the filling of the resin.

The cleaning sheet 100 is arranged between the first mold 3 and the second mold 4 of the mold molding portion 28 and is used for cleaning the inside of the mold molding portion 28, after molding the peripheral portion of the semiconductor chip 24 such as the semiconductor chip 24 mounted on the lead frame 201 and the gold wire 21 predetermined number of times.

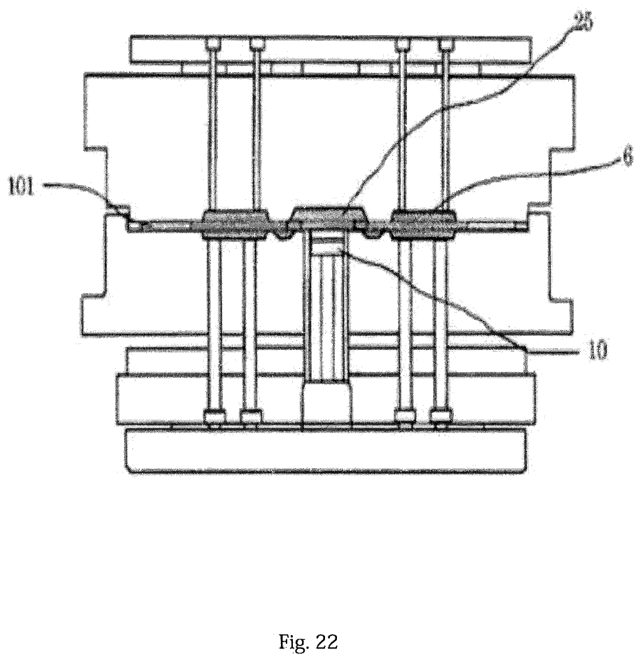

At the time of cleaning, only the cleaning sheet 100 is clamped by the first mold 3 and the second mold 4, and in this state, as shown in FIG. 22, by supplying the cleaning resin 25 to the cavity 6, the cleaning resin 25 passes through the central opening 101 of the cleaning sheet 100 in the cavity 6, and as a result, the cavity 6 is filled with the cleaning resin 25, and the cleaning sheet 100 is filled with the cleaning resin 25 in every corner of the cavity 6 without the cleaning sheet 100 moving up and down (lifting) due to the influence of the resin flow rate.

The cleaning sheet 100 is formed in a size that is guided by a positioning wetting 18 for positioning the upper and lower molds provided on each outer peripheral side of the mating surface 26 of the second mold 4, and the cleaning sheet 100 may be placed according to the positioning wetting 18 on each side. When the cleaning sheet 100 is placed on the second mold 4, it is thus not necessary to perform highly accurate positioning with the second mold 4. Further, when positioning the sheet on the mold without providing a positioning notch, the sheet dimensions may be adjusted to the inner dimensions of each positioning wetting 18.

The QFP 19 shown in FIG. 15 is an example of a semiconductor device that has been molded and assembled by the transfer molding device shown in FIG. 12.

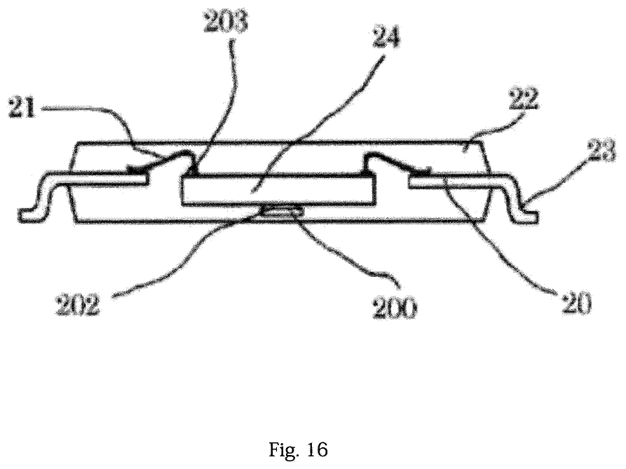

Here, with reference to FIGS. 15 and 16, the structure of the semiconductor device manufactured by the method for manufacturing the semiconductor device of the present invention will be described.

In this embodiment, the case of QFP (Quad Flat Package) shown in FIG. 15 will be described as an example of a resin-molded and surface-mounted semiconductor device using a lead frame.

The QFPs shown in FIGS. 15 and 16 are used, for example, as a microcomputer.

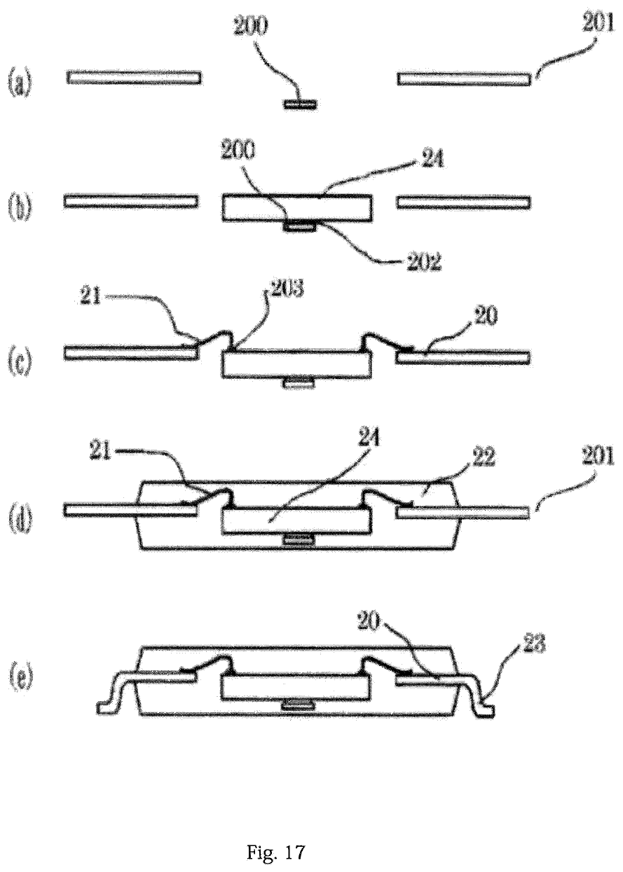

The structure of QFP consists of an inner lead 20 and an outer lead 23 formed by cutting from a tab 200 having a small tab structure on which a semiconductor chip 24 on which a semiconductor integrated circuit is formed are mounted and a lead frame 201 (see FIG. 17), a gold wire 21 (a copper wire other than the gold wire may be used) that electrically connects the bonding pad 203 of the semiconductor chip 24 and the inner lead 20, and a resin mold portion 22 formed by resin molding a semiconductor chip 24, a gold wire 21, and the like.

The QFP 19 has a resin mold portion 22 having a roughly square planar shape.

Further, the semiconductor chip 24 is fixed to the tab 200 by a bonding material 202 such as silver paste.

The plurality of outer leads 23 protruding from the four sides of the resin mold portion 22 are bent and molded in a gull wing shape.

Next, a method of manufacturing the semiconductor device will be described with reference to FIG. 17.

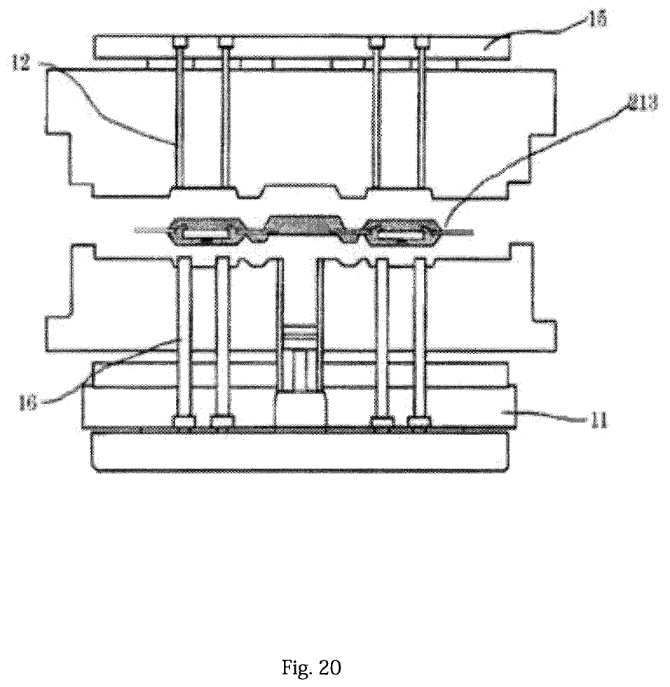

The feature of the method for manufacturing a semiconductor device is that it has a molding (resin molding) process of the semiconductor chip 24 using the transfer molding apparatus shown in FIG. 12, and a cleaning process inside the mold molding portion 28 in the transfer molding apparatus using the cleaning sheet 100 shown in FIG. 20.

The details of the manufacturing method including the molding step and the cleaning step are as follows.

First, as shown in FIG. 17a, the lead frame 201 is prepared.

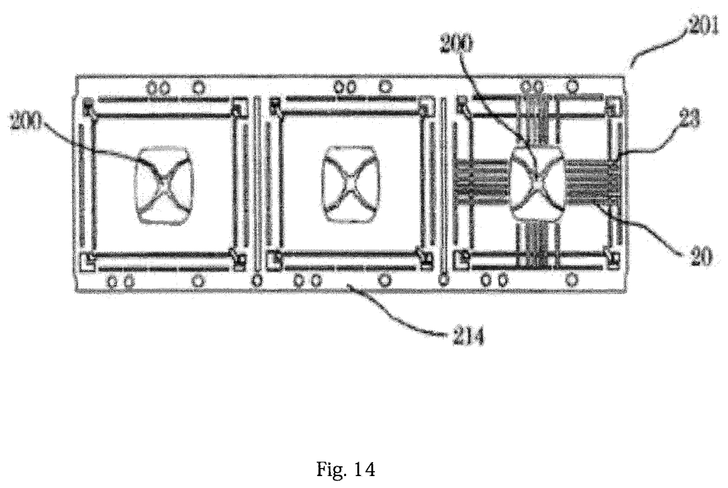

FIG. 14 shows a plan view of the lead frame 201.

For convenience of illustration and explanation, the inner lead 20 and the outer lead 23 are only partially shown.

As shown in FIG. 17b, a die bonding step (also referred to as a fixing step) in which the semiconductor chip 24 is mounted on the tab 200 of the lead frame 201 is performed.

In the die bonding step, as shown in FIG. 17b, a bonding material 202, such as a silver-containing epoxy adhesive, that is, a silver paste is applied onto the tab 200 of the lead frame 201.

Subsequently, the semiconductor chip 24 is mounted on the tab 200 coated with the bonding material 202 by using a collet (not shown).

As shown in FIG. 17c, a wire bonding step is performed in which a bonding pad 203 formed on an electrode of a semiconductor chip 24 mounted on a tab 200 and a corresponding inner lead 20 are bonded by a gold wire 21 to be electrically connected.

Then, as shown in FIG. 17d, in order to protect the semiconductor chip 24 mounted on the lead frame 201 and the peripheral portion of the semiconductor chip 24 such as the gold wire 21 from external atmosphere such as dust and humidity and mechanical impact, the molding process of molding using resin is performed.

As shown in FIG. 17e, using a cutting/molding die (not shown), the residual resin on the front and back surfaces of the frame adhered and formed near the gate 13 is separated from the lead frame 201, and as a result, the unit frame portion having the resin mold portion 22 is separated from the lead frame 201, and the outer lead 23 is bent into a predetermined shape (in this embodiment, a gull wing shape).

Next, the resin molding (molding) step in the molding step will be described with reference to FIGS. 18 to 20.

A solid tablet 212 (molding resin) heated by a preheater is placed on the plunger 10 shown in FIG. 18, and then, the lead frame 201 in which the semiconductor chip 24 and the inner lead 20 are wire-bonded is conveyed from the loader 1 shown in FIG. 12 to the mold 5.

In this state, by moving the second mold 4 closer to the first mold 3, a space including the cavity 6 is formed between the first mold 3 and the second mold 4 forming the mold molding portion 28.

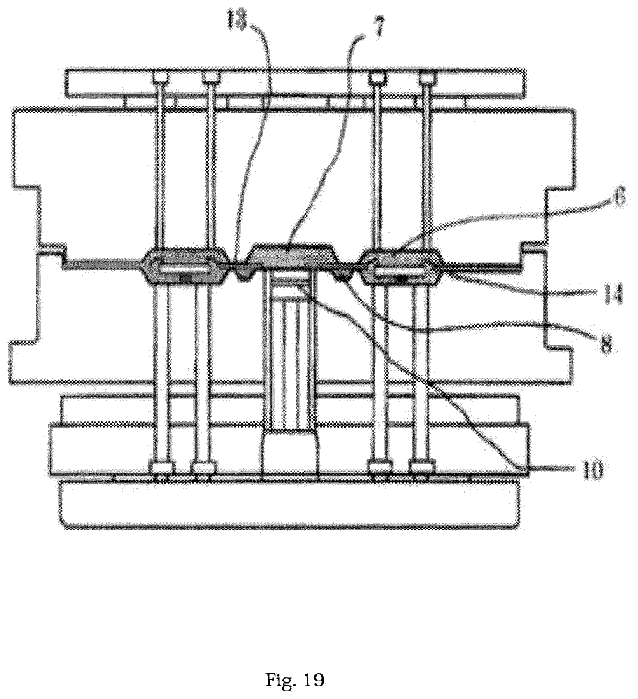

Then, as shown in FIG. 19, when the molten resin for molding is pushed out to the cull 7 by the plunger 10, the molding resin flows into the cavity 6 through the runner 8 and the gate 13. Further, the molding resin filled in the cavity 6 is thermoset by heat and cure, and then the second mold 4 is moved downward to open the mold.

Subsequently, as shown in FIG. 20, the ejector plate 15 is moved in a downward return motion, and the ejector plate 11 is moved in an upward return motion.

As a result, the ejector pins 12 and 16 project to complete the mold opening, and the resin-molded semiconductor device 213 with an outer frame 214 is taken out.

As explained above, the cleaning sheet 100 according to the present embodiment is a cleaning sheet 100 that is interposed between the resin molding mold surfaces and cleans the resin molding mold surface with the cleaning resin, and it is composed of a paper material, and is impregnated with a thermosetting resin and cured from the front surface layer to the back surface layer of the paper material.

That is, since the material of the cleaning sheet 100 is a paper material, it is ultra-cheap and can obtain the maximum economic effect as compared with the conventional dummy frame.

Further, the cleaning sheet 100 according to the present embodiment is impregnated with a thermosetting resin from the front surface layer to the back surface layer of the paper material, and is cured by heating the thermosetting resin at 200° C. to 300° C. for a predetermined time.

In other words, considering that the temperature of the semiconductor mold is 170° C. to 180° C., it can be said that it has sufficient heat resistance and is the most suitable cleaning sheet for a wide variety of molds.

Further, the cleaning sheet 100 according to the present embodiment contains cellulose as a main component, and is thermosetting by impregnating a phenol resin as a thermosetting resin from the front surface layer to the back surface layer of the paper material.

In the paper frame sheet evaluation test, the cleaning sheet 100 does not show fluffing in the cross-sectional observation, which is observed in the conventional product. Thus, it can be expected to significantly suppress the generation of dust during use, which has been a problem with conventional cleaning sheets made of paper materials.

Further, the cleaning sheet 100 according to the present embodiment showed higher hardness than the conventional product in the Rockwell hardness test.

Therefore, it is possible to reduce the warp on the mold as compared with the conventional product, and it can be said that the cleaning sheet is most suitable for a wide variety of molds.

Further, the cleaning sheet 100 according to the present embodiment showed that in the TG-DTA test, the peak of heat generation is lower than that of the conventional product, and the peak shifts to the high temperature range, and that the damping curve of the weight also has a damping point in the high temperature range, and the damping gradient is also gentle.

Therefore, it can be said that it is the most suitable cleaning sheet for a wide variety of molds.

Further, the cleaning sheet 100 according to the present embodiment showed higher rigidity and specific strength than the conventional product in the tear/tensile strength test.

Therefore, it is possible to reduce the warp on the mold as compared with the conventional product, and it can be said that the cleaning sheet is most suitable for a wide variety of molds.

Further, in the dust generation evaluation test, the cleaning sheet 100 according to the present embodiment was found to have less scattering of particles than the conventional product or the non-woven fabric.

Therefore, it can be expected to significantly suppress the generation of dust during use, which has been a problem with conventional products and cleaning sheets using non-woven fabric as a base material.

Further, in the water permeability evaluation test, the cleaning sheet 100 according to the present embodiment was found to have lower water absorption than the conventional product.

That is, since it has been clarified that the water absorption is low in any of the processed cross sections of the cleaning sheet 100, inventory control becomes extremely easy.

Further, the cleaning sheet 100 according to the present embodiment has low dust generation, high rigidity, and low water absorption as described above, so that the sheet is less likely to be deformed or warped.

Along with this characteristic, it is not necessary to wrap with waterproof wax paper, which has been conventionally used for the purpose of preventing moisture from entering the sheet, so that it is possible to reduce costs and man-hours.

Further, since the cleaning sheet 100 according to the present embodiment has a characteristic that the sheet is less likely to be deformed or warped, as shown in 105A to 105D of FIG. 1, for example, the number of openings and the opening area that suppress the deformation and warpage of the sheet can be reduced.

In addition, the cleaning sheet is generally used for semiconductor devices such as DIP, QFP, and TSOP, but since the cleaning sheet 100 according to the present embodiment is less likely to be deformed or warped and has high rigidity, it can also be applied as a dummy frame for MAP, BGA, CSP, and the like, as described above. Therefore, by replacing the expensive substrate frame currently used with a dummy frame having the same physical characteristics as the cleaning sheet 100 according to the present embodiment, a significant cost reduction can be expected.

Further, since the basic configuration of the cleaning sheet 100 according to the present embodiment is a paper material and a resin, the treatment after use is simple and does not affect the environment.

Although the embodiments of the present invention have been described in detail with reference to the drawings, the specific configuration is not limited to this embodiment, and includes designs and the like within a range that does not deviate from the gist of the present invention.

### DESCRIPTION OF THE REFERENCE NUMERALS

1; Loader
2; Unloader
3; First mold
4; Second mold
5; Mold
6; Cavity
7; Cull
8; Runner
9; Pot
10; Plunger
11; Ejector plate
12; Ejector pin
13; Gate
14; Air vent
15; Ejector plate
16; Ejector pin
18; Positioning Wetting
19; QFP (semiconductor device)
20; Inner lead
21; Gold wire
22; Mold portion
23; Outer lead
24; Semiconductor chip
25; Cleaning resin
26; Mating surface
28; Mold molding portion
100; Cleaning sheet
101; Opening
102; Front surface layer
103; Back surface layer
104; Punching cross section
105A; Opening
105B; Opening
105C; Opening
105D; Opening
106; Handle portion
200; Tab
201; Lead frame
202; Joining material
203; Bonding pad
213; Resin-molded semiconductor device with outer frame
214; Outer frame

1. A cleaning sheet that is interposed between the resin molding mold surfaces and cleans the resin molding mold surface with a cleaning resin, characterized in that:
it is made of a paper material, which is impregnated with a thermosetting resin and cured from the front surface layer to the back surface layer of the paper material.

2. The cleaning sheet according to claim 1 characterized in that the thermosetting resin is cured by heating it at 200° C. to 300° C. for a predetermined time.

3. The cleaning sheet according to claim 1 characterized in that the paper material contains cellulose as a main component.

4. The cleaning sheet according to claim 1 characterized in that the thermosetting resin is a phenol resin.

5. The cleaning sheet according to claim 1, wherein,
the cleaning sheet is placed between the first mold and the second mold of a mold consisting of a pair of first molds and a second mold having a cavity block which is a mounting area of a lead frame and a pot holder consisting of a plurality of pots for adding cleaning resin,
characterized in that,
the cleaning sheet has an opening corresponding to at least the cavity block when it is arranged between the first mold and the second mold.

6. A method for manufacturing a semiconductor device, which comprises a step of cleaning the mating surfaces of a mold consisting of a pair of first mold and second mold having a cavity block which is a mounting area of a lead frame and a pot holder consisting of a plurality of pots into which resin is added, using the cleaning sheet according to claim 1,
characterized in that it has the steps of;
preparing the cleaning sheet having an opening corresponding to at least the cavity block when placed between the first mold and the second mold;
installing the cleaning sheet in the mold and clamping the cleaning sheet with the first mold and the second mold;
supplying the cleaning resin from the pot and filling the cavity block with the cleaning resin through the opening of the cleaning sheet;
releasing the cleaning resin and the cleaning sheet from the mold after curing the cleaning resin.

7. The method for manufacturing a semiconductor device according to claim 6, characterized in that the semiconductor device includes at least a DIL-P, a QFP, a MAP, a CSP, a BGA, a diode, and a transistor.

8. A method for manufacturing a cleaning sheet, characterized in that it has the steps of:
impregnating paper material containing cellulose as the main component with phenol resin;
curing the phenol resin by performing a heat treatment including a treatment of heating the paper material impregnated with the phenol resin at least 200° C. to 300° C. for a predetermined time.
